(19) United States
(12) Patent Application Publication
(10) Pub. No.: US 2006/0147058 A1
(43) Pub. Date: Jul. 6, 2006

(54) Electronic audio processing devices and volume control assistance methods

(75) Inventor: Jin-Dar Wang, Banciao City (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: Lite-On Technology Corporation

(21) Appl. No.: 11/168,678

(22) Filed: Jun. 28, 2005

(30) Foreign Application Priority Data
Jan. 3, 2005 (TW) 94100035

(51) Int. Cl. H03G 3/00

(52) U.S. Cl. 381/104; 381/107; 381/109

(57) ABSTRACT

An electronic audio processing device comprises an input unit, an output unit, and a processor coupled with the input unit and the output unit. The input unit receives foreground and background audio. The processor determines if the volume of the foreground and background audio conforms to a conditional relationship, and accordingly outputs notification signals via the output unit.

### BACKGROUND

The invention relates to signal processing, and in particular, to electronic audio processing devices and audio volume determination.

When recording an audio source in a noisy environment or from a source with low volume, a recorder may not obtain the desired sound quality. Although this may be ameliorated by decreasing the distance between a sound recorder and the sound source, the actual quality of the recording is unknown until complete.

Frequently, when speaking on the telephone, people may speak too loudly, disturbing others or too quietly, resulting in reduced audibility.

Audio recorders and telephones are examples of sound processing devices requiring proper manipulation with respect to audio source position and volume thereof.

### SUMMARY

Accordingly, electronic audio processing devices and volume control assistance methods are provided.

An exemplary embodiment of an electronic audio processing device comprises an input unit, an output unit, and a processor coupled with the input unit and the output unit. The input unit receives foreground and background audio. The processor determines if the volume of foreground and background audio conforms to a conditional relationship, and accordingly outputs notification signals via the output unit.

An exemplary embodiment of a volume control assistance method is implemented in an electronic audio processing device comprising an input unit, an output unit, and a processor. Foreground and background audio is first received by the input unit. The processor determines if the volume of the foreground and background audio conforms to a conditional relationship. Notification signals based on the determination are output via the output unit.

### DESCRIPTION OF THE DRAWINGS

The invention can be more fully understood by reading the subsequent detailed description and examples with references made to the accompanying drawings, wherein:

FIG. 1 is a block diagram of a configuration of an exemplary embodiment of an electronic audio processing device;

FIG. 2 is a flowchart of an exemplary embodiment of a volume control assistance method;

FIG. 3 is a block diagram of configuration of an exemplary embodiment of an input unit;

FIG. 4 is a schematic diagram of an exemplary embodiment of an electronic audio processing device; and

FIG. 5 is a flowchart of another exemplary embodiment of volume control assistance method.

### DETAILED DESCRIPTION

Electronic audio processing devices and volume control assistance methods are provided.

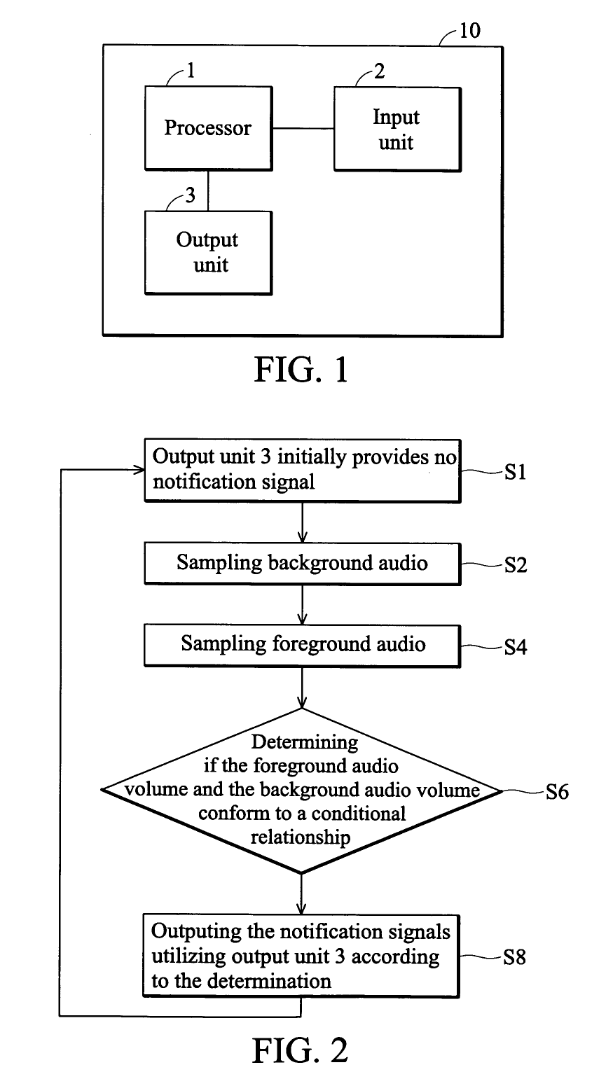

In FIG. 1, electronic audio processing device 10 comprises processor 1, input unit 2, and output unit 3, wherein processor 1 is coupled with input unit 2 and output unit 3. Input unit 2 receives audio signals. Output unit 3 may comprise a display, a speaker, an oscillator, and/or others for outputting notification signals, such as visual, audible, vibratory, or other signals.

Electronic audio processing device 10 may be an audio recorder (such as a voice recorder), a communication device (such as a mobile phone, a wired phone, or VoIP phone), or other audio receiving devices. Electronic audio processing device 10 may comprise a non-volatile memory storing audio signals. Electronic audio processing device 10 may be a communication device transmitting the received audio to another external electronic device and receiving audio signals therefrom.

Electronic audio processing device 10 samples desired audio (referred to as foreground audio), such as a user voice, and other audio (referred to as background audio) from received sound. An exemplary embodiment of a volume control assistance method is described in the following.

Referring to FIG. 2, output unit 3 initially provides no notification signal (step S1). Input unit 2 samples background audio (step S2) and foreground audio (step S4). Please note that step S2 and step S4 may be performed simultaneously. Input unit 2 may comprise a plurality of audio receiving components or one audio receiving component simultaneously sampling background audio and foreground audio.

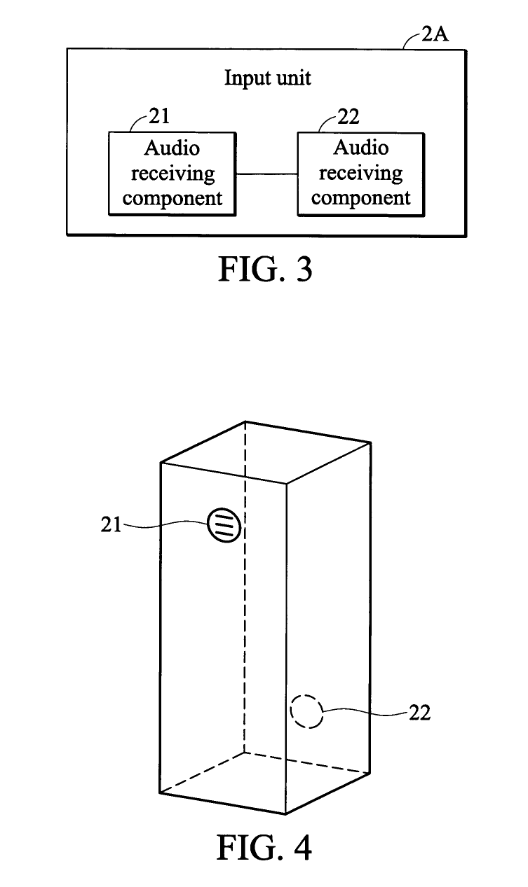

For example, input unit 2A in FIG. 3 is an example of input unit 2, comprising different audio receiving components 21 and 22 respectively receiving audio signals as the foreground audio and the background audio. Audio receiving components 21 and 22 may be located on opposing surface areas of electronic audio processing device 10, as shown in FIG. 4, or other areas facing sources of the foreground audio and the background audio. For example, input unit 2A samples audio signals for a predetermined period, wherein the average volume of audio signals received by audio receiving components 21 in the period is adopted as the foreground audio volume, and the average volume of the audio signals received by audio receiving components 22 in the period is adopted as the background audio volume. In another example, input unit 2A samples audio signals for a predetermined period, wherein the maximum volume of audio signals received by audio receiving components 21 in the period is adopted as the volume of foreground audio, and the minimum volume of audio signals received by audio receiving components 22 in the period is adopted as the volume of background audio. Note that the foreground and background audio can be sampled by other methods.

Processor 1 determines if volume of the foreground audio and volume of the background audio conforms to a conditional relationship (step S6).

For example, the foreground audio volume and the background audio volume are represented by variables, Smax and Smin respectively. The conditional relationship may be that the difference between the foreground audio volume and the background audio volume must be less than a maximum volume difference Dmax.

Finally, processor 1 outputs the notification signals utilizing output unit 3 according to the determination (step S8). For example, when the foreground audio volume and the background audio volume do not conform to the conditional relationship, the processor outputs the notification signals utilizing output unit 3.

With reference to the described example, if Smax−Smin<Dmax, processor 1 does not output the notification signals. If Smax−Smin>Dmax, processor 1 outputs the notification signals.

Note that output device 3 may not output notification signals until the foreground audio volume and the background audio volume conform to the conditional relationship. Processor 1 repeats the described steps.

In another example, the conditional relationship is the ratio of the foreground audio volume to the background audio volume must be less than a maximum volume ratio Pmax. If Smax/Smin<Pmax, processor 1 does not output the notification signals. If Smax/Smin>Pmax, processor 1 outputs the notification signals.

Similarly, in some examples, the conditional relationship is the difference between the foreground audio volume and the background audio volume must be greater than a minimum volume difference Dmin or the ratio of the foreground audio volume to the background audio volume must be greater than a minimum volume ratio Pmin.

Input unit 2 samples audio signals in a predetermined period. Processor 1 may adopt the maximum volume of audio signals sampled by input unit 2 in the period as the volume of foreground audio and minimum volume of audio signals sampled by input unit 2 in the period as the background audio volume, as described in the following.

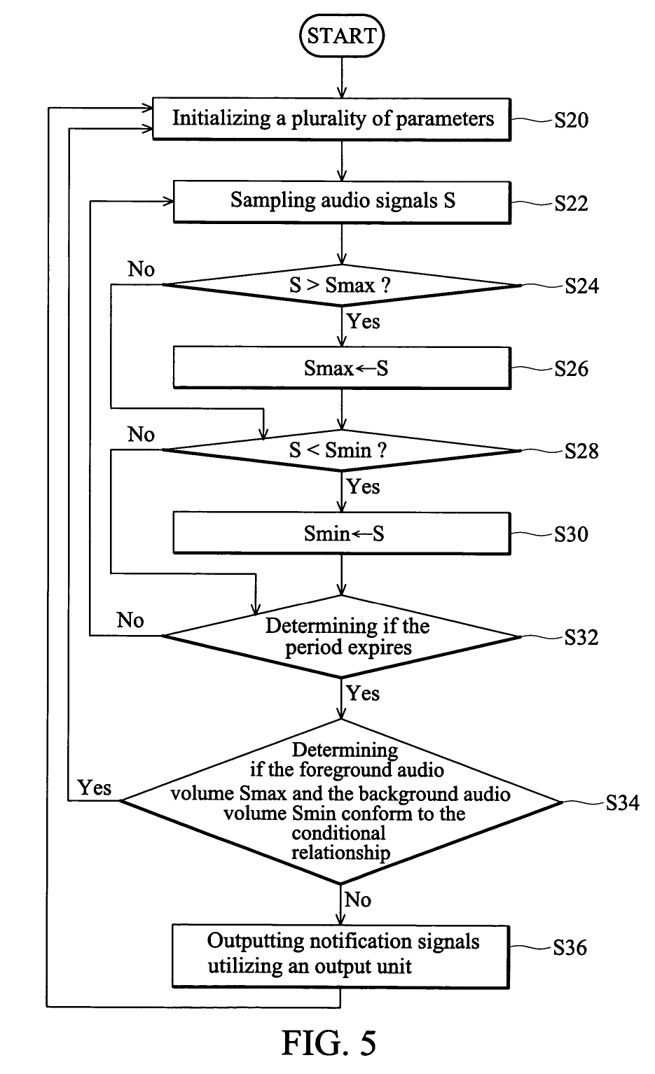

Referring to FIG. 5, processor 1 initializes a plurality of parameters comprising foreground audio volume Smax and background audio volume Smin (step S20). For example, processor 1 assigns Smax zero and Smin an extremely large value. Next, processor 1 samples audio signals S utilizing input unit 2 (step S22) and determines if S>Smax (step S24). If so, processor 1 assigns Smax S (step S26). If not, step S28 is performed. Processor 1 determines if S<Smin (step S28). If so, processor 1 assigns Smin S (step S30). If not, step S32 is performed. Processor 1 determines if the period has expired (step S32). If not, step S22 is repeated. Processor 1 acquires maximum volume Smax and minimum volume Smin in the period by repeating steps S22 to S32. As described in previous examples, if the predetermined period expires, processor 1 determines if the foreground audio volume Smax and the background audio volume Smin conform to the conditional relationship (step S34). If so, step S20 is repeated. If not, processor 1 outputs notification signals utilizing output unit 3 (step S36). For example, processor 1 utilizes output unit 3 to trigger vibration based on the determination.

Output unit 3 may comprise a display, speaker, oscillator, or others. Processor 1, for example, outputs audible notification signals utilizing a speaker, visual notification signals utilizing a display, and/or other signals utilizing output unit 3. Output unit 3 may comprise an audio output component providing audio. Processor 1 determines whether to mix a predetermined audio signal with the raw audio provided by the audio output component according to the determination and outputs the mixed audio signal utilizing the audio output component. In an exemplary mobile phone implementing the volume control assistance method, when the foreground audio is too loud, an output unit thereof may mix a predetermined audio signal into raw output audio for notification. In an exemplary voice recorder implementing the volume control assistance method, when the foreground audio is too quiet, an output unit thereof may output predetermined audio signals for notification. Output unit 3 may comprise an audio output component with volume adjuster. Processor 1 outputs volume adjustment signals for modification of audio volume provided by output unit 3 based on the determination. For example, if Smax−Smin>Dmax, processor 1 outputs volume adjustment signals to decrease (or increase) audio volume provided by output unit 3. Alternatively, if Smax−Smin<Dmin, processor 1 outputs volume adjustment signals to increase (or decrease) audio volume provided by output unit 3.

Electronic audio processing device 10 repeats the described steps. Additionally, electronic audio processing device 10 may provide an interface for adjustment of the conditional relationships (such as Dmax, Dmin, Pmax, and Pmin) and switch of volume control assistance functions on or off. Thus an electronic audio processing device may output notification signals when the foreground audio is too loud or too quiet.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An electronic audio processing device, comprising:
an input unit for receiving foreground and background audio;
an output unit for outputting notification signals; and
a processor coupled with the input unit and the output unit, determining if volume of the foreground and background audio conforms to a conditional relationship, and accordingly outputting the notification signals utilizing the output unit.

2. The device as claimed in claim 1, wherein the conditional relationship prescribes a relationship between the volume of the foreground and the volume of background audio.

3. The device as claimed in claim 2, wherein when the volume of the foreground and the volume of background audio do not conform to the conditional relationship, the processor outputs the notification signals utilizing the output unit.

4. The device as claimed in claim 2, wherein the conditional relationship is the difference between the volume of the foreground and the volume of background audio must be less than a maximum volume difference.

5. The device as claimed in claim 2, wherein the conditional relationship is the difference between the volume of the foreground and the volume of background audio must be greater than a minimum volume difference.

6. The device as claimed in claim 2, wherein the conditional relationship is the ratio of the volume of the foreground to the volume of background audio must be less than a maximum volume ratio.

7. The device as claimed in claim 2, wherein the conditional relationship is the ratio of the volume of the foreground to the volume of background audio must be greater than a minimum volume ratio.

8. The device as claimed in claim 1, wherein the input unit comprises a first audio input component and a second audio input component respectively receiving the foreground and the background audio, and the first audio input component and the second audio input component are configured to respectively face sources of the foreground and the background audio.

9. The device as claimed in claim 1, wherein the input unit comprises an audio input component by which the processor samples audio signals for a predetermined period, the highest volume of sampled audio signals in the predetermined period is adopted as the volume of the foreground audio, and the lowest volume of sampled audio signals in the predetermined period is adopted as the volume of the background audio.

10. The device as claimed in claim 1, wherein the output unit comprises an audio output component, the processor generates a volume control signal for adjusting the volume at which the output unit provides sound according to the determination.

11. The device as claimed in claim 1, wherein the output unit comprises an audio output component providing audio, the processor determines whether to mix a predetermined audio signal with the audio provided by the audio output component according to the determination.

12. A volume control assistance method, implemented in an electronic audio processing device comprising an input unit, an output unit, and a processor, comprising:
receiving foreground and background audio by the input unit;
determining, by the processor, if the volume of the foreground audio and the volume of the background audio conforms to a conditional relationship; and
outputting notification signals utilizing the output unit based on the determination.

13. The method as claimed in claim 12, wherein the conditional relationship prescribes a relationship between the volume of the foreground and the volume of background audio.

14. The method as claimed in claim 13, further comprising, when the volume of the foreground and the volume of background audio do not conform to the conditional relationship, outputting the notification signals utilizing the output unit.

15. The method as claimed in claim 13, wherein the conditional relationship is the difference between the volume of the foreground and the volume of background audio must be less than a maximum volume difference.

16. The method as claimed in claim 13, wherein the conditional relationship is the difference between the volume of the foreground and the volume of background audio must be greater than a minimum volume difference.

17. The method as claimed in claim 13, wherein the conditional relationship is the ratio of the volume of the foreground to the volume of background audio must be less than a maximum volume ratio.

18. The method as claimed in claim 13, wherein the conditional relationship is the ratio of the volume of the foreground to the volume of background audio must be greater than a minimum volume ratio.

19. The method as claimed in claim 12, wherein the input unit samples audio signals in a predetermined period, the highest volume of sampled audio signals in the predetermined period is adopted as the volume of the foreground audio, and the lowest volume of sampled audio signals in the predetermined period is adopted as the volume of the background audio.

20. The method as claimed in claim 12, wherein the input unit comprises a first audio input component and a second and samples audio signals in a predetermined period, average volume of audio signals sampled by the first audio input component in the predetermined period is adopted as the volume of the foreground audio, and average volume of audio signals sampled by the second audio input component in the predetermined period is adopted as the volume of the background audio.
